(19) United States
(12) Patent Application Publication
(10) Pub. No.: US 2011/0260181 A1
(43) Pub. Date: Oct. 27, 2011

(54) Mounting structure for LEDs, LED assembly, LED assembly socket, method for forming a mounting structure

(75) Inventors: Siegmund Kobilke, Ingolstadt (DE); Frank Gindele, Schweitenkirchen (DE)

(73) Assignee: PERKINELMER ELCOS GMBH, Pfaffenhofen (DE)

(21) Appl. No.: 12/671,700

(22) PCT Filed: Jul. 21, 2008
(86) PCT No.: PCT/EP08/05959

§ 371 Date: Jun. 13, 2011

(30) Foreign Application Priority Data
Aug. 2, 2007 (DE) 10 2007 036 226.0

(51) Int. Cl. H01L 33/64

(52) U.S. Cl. 257/89; 257/98; 438/26; 257/E33.075

(57) ABSTRACT

A mounting structure for at least one LED has a substrate made of silicon and/or another semiconductor, wherein at least one mounting portion formed in a front surface of the substrate for mounting at least one LED chip thereon, and cooling grooves or channels for a cooling fluid are formed in the substrate, preferably in or beneath a rear surface thereof.

### BACKGROUND

The aspects of the disclosed embodiments relate to a mounting structure for LEDs, to an LED assembly, to a socket for an LED assembly, and to a method for forming a mounting structure.

LEDs (light emitting diodes) are increasingly used for illumination and display purposes. The invention of the blue LED has significantly increased the available colour spectrum for LED applications such that practically all colours can be generated either through a single LED of appropriate construction or through juxtaposing plural LEDs of different colours and appropriately controlling their respective intensities. In an increasing manner, LEDs are used as panels, i.e. in an arrangement where plural LEDs cover, in a preferably regular arrangement, a certain area. Again, such panels may be used for illumination purposes, or, if resolution allows it, for display purposes.

One technique for arranging plural LEDs is providing them on a common substrate, for example a silicon substrate. This allows using well-known technologies for providing wiring and the like. Although LEDs are in their efficiency—as regards light output—much better than many other illumination technologies, nevertheless also LEDs produce heat. The closer LEDs are packed, the more will heat be a problem. If inherent heat removal properties are insufficient, measures must be taken for removing heat. Metal cooling bodies are used for such purposes. Such cooling bodies may be attached to accessible surface parts of the substrate holding the LEDs. Particularly, they may be attached to the rear side of such a substrate. This, however, makes LED arrays heavy and voluminous.

A further desire is to have the possibility to easily determine direction properties of light emission, i.e. light output over viewing angle. Lenses and mirrors are used for adjusting desired characteristics. However, such components must be provided and make again the device bulky or expensive.

### SUMMARY

One aspect of the disclosed embodiments presents an LED mounting structure, an LED assembly and a socket for such an assembly rendering improved thermal properties of an LED assembly. A further aspect includes an LED mounting structure, an LED assembly and a socket for an LED assembly allowing at the same time improved thermal properties and an easy way of defining angular emission characteristics.

These aspects are accomplished in accordance with the features of the independent claims. Dependent claims are directed on preferred embodiments.

According to the aspects of the disclosed embodiments, an LED mounting structure is made of a semiconductor or ceramics substrate, such as a silicon substrate or AlN. It may be doped or undoped. It may be poly-silicon. In this structure, cooling grooves or cooling channels are formed for circulating a cooling fluid for removing the heat of LED chips also provided on the substrate.

The LED chips may be placed in recesses formed in the substrate. The walls of the recesses may be made reflective and may be plane or curved so that they have beam shaping properties.

The recesses and/or the grooves or channels for cooling may be formed through micromachining, particularly through etching, such as wet etching or dry etching or reactive ion etching (RIE) or deep reactive ion etching (DRIE). An inductively coupled plasma (ICP) may be used as etchant. The structures may be formed by providing an etch-mask on the surface to be etched and then etching the free surface portion in a desired way. The mask may be or contain a metal, such as aluminum. Cooling grooves/channels and recesses for LED chips may be provided on opposing surfaces of a substrate.

In an LED assembly, LED chips may be provided on the mounting structure such that they are individually drivable. The LED chips may be provided in a recess, respectively. Cooling channels are formed either immediately in the substrate as mentioned above or by closing grooves in the substrate surface by a suitable cover. Cooling fluid may circulate through the channels for re-moving heat from the LEDs.

Above an LED chip, and possibly within a recess, may be a colour conversion substance and/or a scattering substance. The colour conversion substance may convert photons of higher energy (shorter wavelength, blue or UV range) into photons of lower energy (longer wavelength, green, yellow, red). The mixture may be such that an overall impression of white light or any other colour characteristics is obtained. The diffractive substance may have scattering particles for scattering light within the substance in order to provide a better mixture, avoid border effects and the like.

The LED assembly also has first electric connecting means allowing electrical connection to external components, and has first fluid connecting means allowing fluid connection of the cooling channels to external cooling components. The external electric components may be devices for controlling LED arrays. The external cooling components may comprise a cooling fluid and a circulating means such as a pump for circulating the cooling fluid through the cooling channels. The connecting means may be formed plug-like, i.e. allowing connecting and disconnecting through a simple insertion or removal operation. The cooling fluid may be a liquid such as water or an oil, or it can be air or some kind of gas, too.

Connection of the LED assembly to the external components may be made through a socket. The socket may have a receptacle for an LED assembly and may have mating electric and fluid connecting means. It may further have mechanical holding means. A socket may have plural receptacles for plural LED assemblies.

A method for forming a mounting structure for at least one LED comprises the steps of preparing a substrate (11) comprising silicon and/or another semiconductor and/or any other ceramics, and forming cooling grooves (16, 16a, 16b) or channels for a cooling fluid in the substrate, preferably in or beneath a rear surface (13) thereof.

### BRIEF DESCRIPTION OF THE DRAWINGS

In the following, aspects of the disclosed embodiments will be described with reference to the drawings, in which

FIG. 1 is a sectional view of a mounting structure,

FIG. 2 is a sectional view through an LED formed in the mounting structure,

FIG. 3 is schematic plan view on an LED assembly,

FIG. 4 is a sectional view of another embodiment of the mounting structure,

FIG. 5 is a schematic overall view of an LED assembly,

FIG. 6 is a schematic view of a socket,

FIG. 7 is a schematic side view of another embodiment of the LED assembly,

FIG. 8 is another embodiment of a socket, FIG. 9 shows in combination plural more features and aspects of the disclosed embodiments, and

FIG. 10 shows an assembly with a thermoelectrical cooling element.

### DETAILED DESCRIPTION OF THE DISCLOSED EMBODIMENTS

Generally in this specification, same reference numerals denote same features. Features described in this specification shall be considered to be freely combinable with each other, as far as they do not exclude each other for technical reasons.

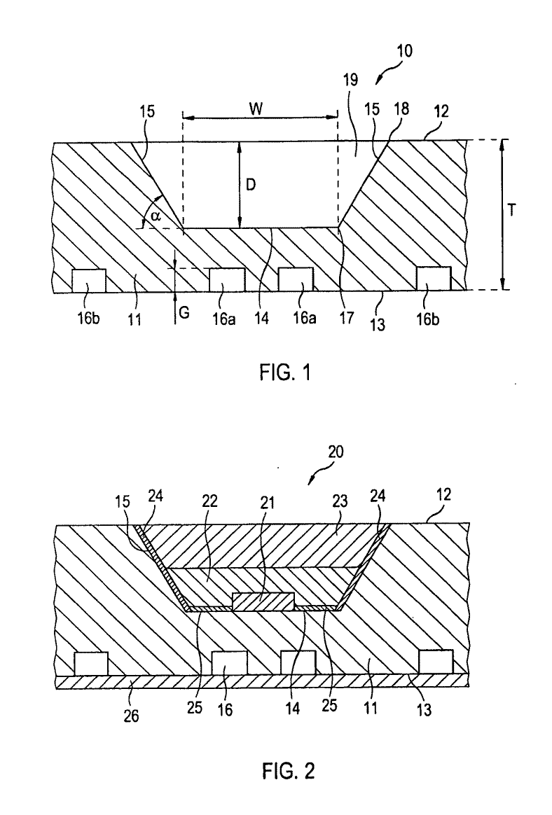

FIG. 1 is a sectional view of a part of a mounting structure. It comprises a substrate 11. It may be of flat, disk-like overall shape having two major surfaces, namely a front surface 12 and a rear surface 13. The substrate may be or comprise a semi-conductor, doped or undoped. It may particularly be or comprise silicon, which may be polycrystalline silicon or a single crystal. Alternatively the substrate may be or comprise a ceramics such as AlN.

A recess 19 is formed in the front surface 12. The recess has sidewalls 15 and a bottom portion 14 suitable for placing at least one LED chip thereon. An LED chip is a semiconductor element to which voltage may be applied and which, thereupon, emits radiation in the visible wavelength range or in the UV range. The recess may be a cavity.

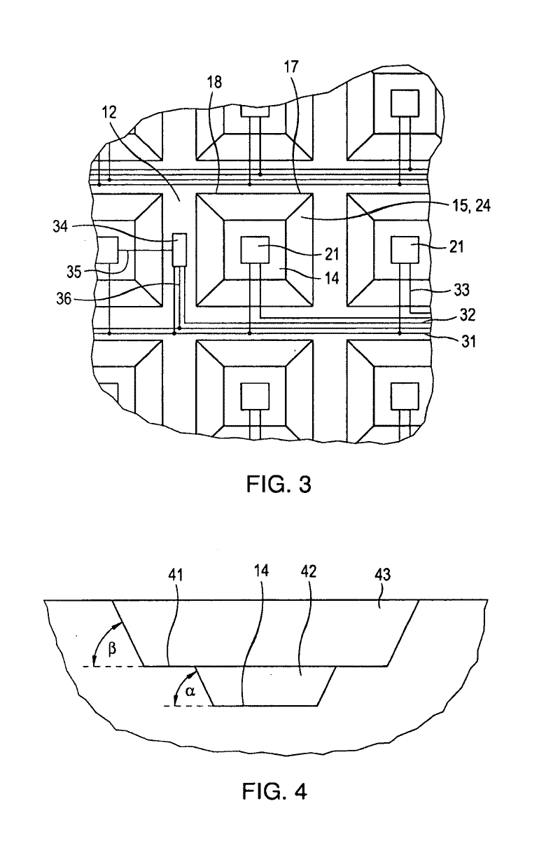

The recess 19 may be formed by an etching technique, for example by wet etching. The bottom portion may be a flat or curved plane, and also the sidewalls may be respective flat planes or may at least comprise such portions. In a top plane view, both the contour 18 of the recess in the front surface 12 and the contour 17 of the bottom portion 14 may be rectangular or square or of another shape, as schematically shown in FIG. 3. The sidewalls 15 may have an inclination angle α. It may be determined by etching properties, for example, may be given through the crystal orientation of the substrate in combination with effect of the etchant. An angle of α=54.7° or 35.3° (90°-54.7°) may appear without further measures and may be taken as such.

Other geometrical quantities such as the depth D of the recess (distance of bottom portion plane 14 from the front surface plane 12) or the width W of the bottom portion may be set. Likewise, the overall thickness T of the substrate 11 will be selected to have an appropriate value.

Grooves 16 or closed channels preferably of a complex system of microchannels with a high surface to volume ratio may also be formed in the substrate 11. They may be formed on the rear surface 13. The channels may be formed right underneath a recess (grooves 16a), or they may be formed between adjacent recesses, i.e. where substrate 11 has more or less its entire thickness (grooves 16b in FIG. 1). Grooves may also be provided below the sidewalls 15, what is a compromise between cooling properties and mechanical strength. Placing the grooves right below the recesses is better for heat removal, whereas placing them between adjacent recesses is better for preserving mechanical stability. One or plural grooves—may be provided per recess. In the range of one recess, the grooves may be straight or bent or meandering. They may run diagonally (20°-70° to the edges 18 of the recess. The grooves 16 may also be formed by etching, particularly by wet etching or by dry etching, such as reactive ion etching, preferably with the above-addressed techniques (RIE, DRIE, ICP).

The mounting structure shown in FIG. 1 has the advantage that it may be manufactured with well-known techniques, so that they are easily feasible. At the same time, the structure provides cooling in that cooling channels or grooves are formed, and it has beam shaping properties in that through the geometric definitions of angle α, depth D, and width W, the direction characteristics of the emanating radiation can be determined to some extent.

The mounting structure may comprise, or be adapted to receive, wiring for providing electrical connection to LED chips to be mounted. The wiring may comprise leads on accessible surface portions and also wire bonding provisions, particularly bond pads. These may be provided on the substrate surface and/or on a recess side wall and/or on the bottom portion.

FIG. 2 shows an LED 20 formed in the mounting structure 10. An LED chip 21 is placed on the bottom portion 14 of the recess 19. Electric wiring is provided, but not shown in FIG. 2. It may come from wiring on the front surface 12, reaching down the sidewalls 15 and on the bottom portion 14 towards the LED chip 21. It may, however, in certain embodiments also come from the rear surface 13, passing through not shown through-holes. In a preferred embodiment, the wiring towards the LED chips may first run away from the LED chip 21 along the surface of the recess and the front surface 12 and may, from there, reach to the rear surface 13 through a through-hole.

The LED chip 21 may be symmetrically positioned in the bottom portion, i.e. in the middle thereof, or asymmetrically, if desired for some reason. The sidewalls 15 may fully or in parts be or be made reflective. For this, they may have a reflective surface or film 24 formed or coated thereon. Wiring and electrical contacting may be on top of the reflective layer 24, or between it and sidewall 15. Likewise, the bottom portion 14 may be covered with a reflective layer 25. Thus, radiation impinging on the sidewalls from the LED chip 21 or from scattering particles is reflected outwards so that an overall beam shaping within one half space in the forward direction of FIG. 2 is obtained.

A colour conversion substance 22 may be provided above the LED chip 21. It may have been liquid, may have been poured into the recess and may have solidified there. The LED chip 21 may emit radiation comprising comparatively short wavelength, i.e. in the blue range or even in the UV range. The conversion substance 22 may convert photons from this radiation into longer wave-length photons, i.e. towards green or yellow or even red. The converting substance 22 may be a mixture of various differing substances so that different conversion outputs are obtained. The mixture and general design may be such that a colour output of a desired characteristic is obtained, for example more or less white light. Then, the colour conversion substance 22 is designed such that a significant part of the LED radiation escapes unchanged, part of the radiation is converted towards green, other parts are converted towards yellow and red, and the intensities are set such that the superposition of blue, green, yellow and red renders more or less white light.

Further, a scattering substance 23 may be provided above the LED chip 21, and preferably above the conversion substance 22. It may, e.g., be a transparent substance with scattering particles dispersed therein. This provides for reflections and multi-reflections of rays before exiting LED 20, so that the light source is more diffuse than without the scattering substance.

Grooves 16 on the rear surface 13 are covered by a cover 26 for closing them such that cooling channels are formed. The cover 26 may be attached to the rear surface 13 through an appropriate technology. The attachment may be liquid-tight in case the cooling fluid is a liquid. The channels 16 may be series-connected or parallel-connected to each other. A cooling fluid is forced to circulate therethrough, so that it removes heat generated by the operation of the LED. Thus, an enhanced cooling performance is obtained.

FIG. 3 shows a plan view on the front surface 12 (i.e. in a downward direction in the drawing plane of FIG. 1). It shows plural recesses regularly arranged. Both the outer contour 18 and the inner contour 17 are rectangular/square or curved. The arrangement: of the various recesses follows a regular pattern, particularly a rectangular/square matrix. Between adjacent recesses, portions 12 of the front surface may remain. Wiring 31 and 32 is provided on the mounting structure. The wiring may particularly be provided on the remaining portions of the front surface 12. Wiring may comprise power lines 31 (supply voltage and ground) and signal lines 32 for individually driving the various LED chips 21. FIG. 3 shows in combination two possible embodiments: the LED chip 21 in the middle of the Figure receives its signal directly from a signal line 32 and may be connected to a ground line of power supply lines 31. The LED chip on the left side of the Figure receives its signal from a semiconductor 34 also provided on the mounting structure, particularly on the front surface 12. The semiconductor may be or comprise a transistor or a diode such as a Zener diode. The transistor may be connected to the power supply line 31 and also to a signal line, and may supply driving signals to the LED chip 21 through a line 35.

The LED chips 21 may be of same spectral characteristics or may have different spectral characteristics, particularly different colours. Further, in one recess 19 one LED chip or plural LED chips may be provided. “Plural LED chips” in this context means that plural optical active regions are provided. They may be provided on one and the same physical chip. These plural LED chips may again be of different spectral characteristics, particularly of different colour. They may individually be driven through appropriate wiring and circuitry. When plural LED chips of different spectral characteristics are provided in one recess, and plural such recesses are provided in a square (m*n) or other array, then the individual LED chips may be arranged such that they are placed in varying areas of the recesses when comparing them with each other. In terms of north N, east E, south S and west W, e.g. a red LED chip may be placed in one recess in the NW corner, in another recess in the NE corner, in another recess in the SE corner, and in the SW corner in yet another recess. This improves colour mix particularly in view of asymmetric light guiding properties at asymmetric arrangements of individual chips. The arrangement may be such that seen across plural or all recesses of a mounting structure, the LED chips of same or similar spectral characteristics (colour) are equally distributed about all possible positions within one recess.

Circuit elements and semiconductors 34 provided on the mounting structure may be of comparatively simple switching structure (such as a transistor 34) or may be of, or comprise, a more complex analogue and/or digital structure for signal processing, signal distributing, scanning, multiplexing, data storing and related complex driving or signal processing and generating tasks for the various LEDs.

FIG. 4 shows another embodiment of forming the recess 19. There, the recess has a step structure in that in the cross-section an intermediate step 41 is provided. Although FIG. 4 shows only one such step, plural of them may be provided. The overall recess has an inner part 42 and an outer part 43. At the lowermost bottom portion 14 the LED chip may be placed. The step structure provides different reflection characteristics. Again, the side walls 15, the bottom portion 14 and the step portion 41 may be reflective. Again, a conversion substance and a scattering substance may be filled into respective portions of the recess. Preferably, the scattering substance is provided above the conversion substance.

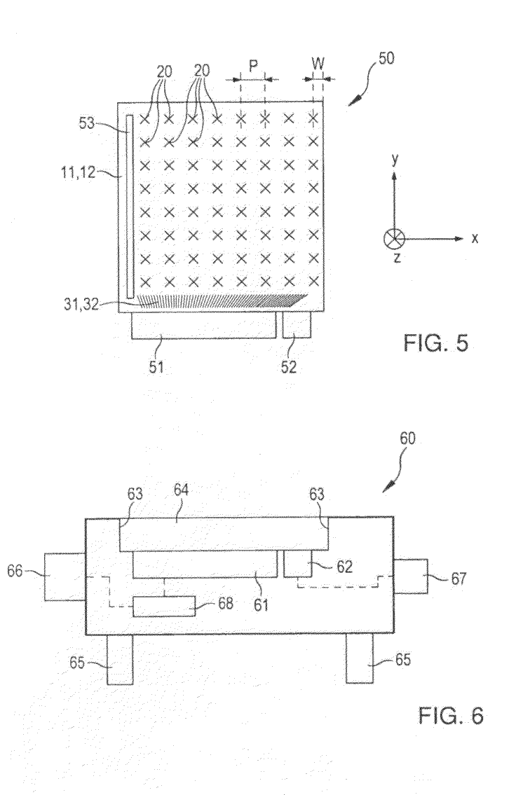

FIG. 5 shows a schematic view of the overall LED assembly 50. Little crosses mark the position of LEDs 20 and/or recess 19 schematically. An 8*8 array is shown. The assembly has first electric connection means 51 and first fluid connection means 52. The first electric connecting means 51 connect to the wiring 31, 32 which is further connected to the LEDs 20. The first electric connecting portion allows electrical connection to external electric components having a corresponding, mating connecting means. The first fluid connecting means 52 is in fluid connection to the channels 16 formed by the mounting structure, possibly together with cover 26. It may have a source channel and a drain channel. The electric connecting means and fluid connecting means are preferably designed and arranged plug-like and such that they have a parallel insertion direction to a corresponding socket, so that through a mounting operation/movement of the LED assembly the desired electric and fluid connections can be established at the same time. The FIG. 5 embodiment has the mounting/dismounting direction in the plane of the front surface 12, i.e. in the x-y-plane. The electric connecting portion may have signal contacts and power contacts as required.

The first electric connecting means 51 may also be or comprise bond pads or connecting pads allowing the attachment of bond wires from/towards external devices, or allowing contacting through spring contacts. Such pads may be provided on a side surface 70 of the assembly or on the front surface 12 or on the rear surface 13.

53 schematically indicates circuitry provided on the LED assembly. It may be a digital circuit. The wiring from the electric connecting portion 51 may go to the circuitry 53 rather than directly to the LEDs 20. Wiring may then go from the circuitry 53 to the LEDs 20. Different from what is shown, circuitry 53 may be provided between rows or columns of LEDs 20, or it may be provided on the rear side of the assembly. Circuitry 53 may be of more or less complex structure. It may be a comparatively simple signal relay circuit, and vice versa it may be a complex processing structure receiving input instructions from the first electric connecting means 51 in a completely different format than that required by individual LEDs. Likewise, the clock frequency of communication of circuitry 53 with external devices may be very different from the operating frequency of the LEDs 20. Particularly, it may be much higher.

Depending on the field of use, the LED chips of the assembly may all be individually drivable (e.g. for display use), or some or all of them may be driven commonly (e.g. for illumination use).

FIG. 6 shows a socket 60 for an LED assembly 50. The socket has a receptacle 64 for an LED assembly 50. The receptacle 64 is basically a mounting portion which may provide electric connection, fluid connection and mechanical connection through appropriate means. The socket 60 has a second electrical connecting means 61 and a second fluid connecting means 62 which respectively mate with the first electric and first fluid connecting means 51, 52 of the LED assembly shown in FIG. 5. The respective connections may be plug-like connections so that insertion and removal of the assembly 50 into or from the socket 60, and thus establishing or separating electric and fluid connections, can be done through an insertion or removal operation, such as a plugging movement or de-plugging movement. The electric and fluid connecting means have preferably the same insertion and removal direction.

The socket 60 may itself have third electric connecting means 66 and third fluid connecting means 67 adapted to connection to other components. These third connecting means may be of more rugged construction than the first and second connecting means. Socket 60 may further comprise circuitry 68 between second and third connecting means 61 and 66. This circuitry may provide for signal shaping, signal distribution, and the like. Third electric connecting means 66 may be formed according to a mechanical or electrical standard, such as a PC card connector, USB, PCMCIA or the like. Socket 60 may also have mechanical connecting means 65 for connecting it mechanically to a desired base. Third fluid connecting means 67 may comprise a connector towards a fluid pipe so that fluid can be supplied and discharged.

63 symbolizes a mechanical holding portion for mechanically holding the LED assembly 50 in the socket 60. The mechanical holding portion 63 may be built more or less integrally with the second electrical and fluid connecting means.

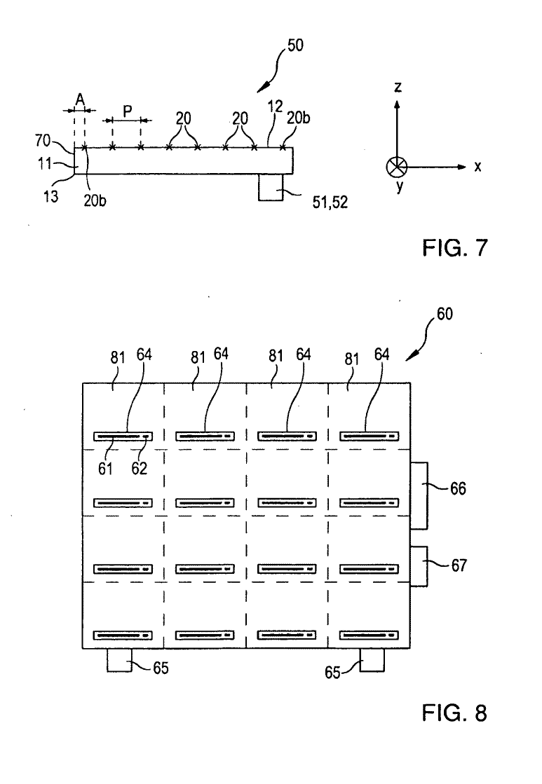

FIG. 7 shows schematically another embodiment of the LED assembly 50. It is a side view similar to the views shown in FIGS. 1 and 2. The little x-es symbolize LEDs and/or recesses. They are arranged under a certain pitch P. The distance A of the centre of the diodes 20b at the border of the assembly to the edge 70 of the assembly is not more than half the pitch P.

Further, the first fluid connecting means 52 and preferably also the first electric connection means 51 may be provided on the rear surface 13 of the assembly. Through this construction, it becomes possible to use the assemblies 50 as tiles by juxtaposing plural of them for uniformly filling an area larger than the area of one assembly 50.

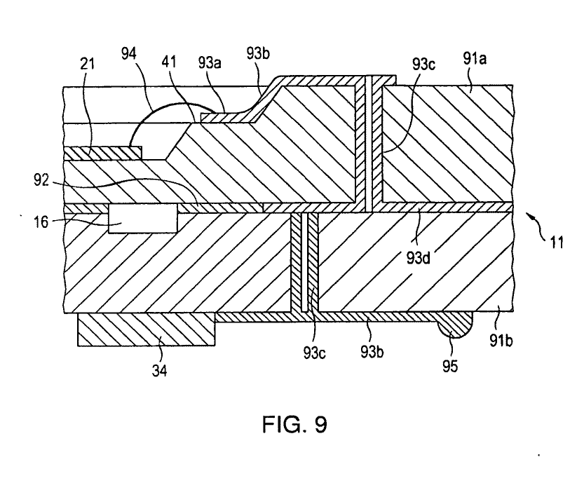

FIG. 8 shows a corresponding socket 60. It has plural receptacles 64 for plural LED assemblies 50. The dashed lines in FIG. 8 indicate the respective mounting positions of the various LED assemblies. One receptacle 64 is allocated to each mounting position 81. The respective second connecting means 61 and 62 for electric and fluid supply may be connected to (not shown) circuitry 53 which makes appropriate distributions.

FIG. 9 shows in combination plural more possible features and embodiments of the mounting structure or LED assembly.

The substrate 11 comprises two or plural stacked layers 91a, 91b which may be individually manufactured and then stacked and bonded with each other. The layers may be of same or different materials. For example, the LED chip side layer 91a may be of a single crystal silicon material, whereas the back side layer 91b may be of polycrystalline silicon or other materials. Combinations of silicon, metal, resin and/or ceramic layers are possible. At least one of them, preferably the LED chip side layer 91a, may be or comprise silicon. Single crystal or poly Si for the front surface layer 91a and ceramics for the rear surface layer 91b is a preferred combination.

The thermal expansion coefficients of adjacent layers match each other preferably within a range of +/−10%, preferably +/−5%. 92 symbolizes some kind of adhesive or bonding structure for mechanically connecting two adjacent layers with each other.

The cooling structure may be provided at the interface between adjacent layers. They may be formed such that grooves 16 are formed in the surface of one of the layers which are covered and closed for forming channels by the other layer. Shown is the case that the grooves are formed in the rear surface layer 91b, and the cover is the front surface layer 91a, but it may also be vice versa.

An analogue and/or digital circuit 34 may be provided on the mounting structure. Compared to the LED chip mounting side, it may be on the opposite side. In a widthwise (vertical in FIG. 9) direction, and/or seen along a line drawn from the circuit to the nearest LED mounting area or chip, the cooling channels 16 may be between the LED chip 21 or its mounting area and the circuit 34. The circuit may also be provided in a (not shown) recess, particularly such that it does not inhibit electric contacting means in their function. Depending on the complexity of circuit 34 it may be comparatively large and may be larger than the area of one or plural recesses. It—and possibly its mounting recess—may then be centred in the overall mounting surface, and electrical contacting means towards external may be provided at the remaining rim.

One or more or all of the side walls of the cooling channels 16 and/or of the possibly provided circuit mounting recess may be vertical or inclined in the same way as the walls of an LED chip recess 19.

Electrically contacting the LED chips 21 may be made by bonding from the respective chip towards bond pads 93a on a step 41 as shown in FIG. 4. 94 symbolizes a bond line. The pads 93a may be part of a structured wiring 93 having portions 93b formed in the recess and/or on the substrate surface and possibly also comprising through-contacts 93c towards the other surface of a layer 91a, 91b or the (stacked) substrate. Likewise, one or both of the interface surfaces of stacked layers 91a, 91b may comprise wiring 93d for accomplishing a suitable signal distribution. The wiring may be formed by the remains of an etched metal layer, such as an Al layer. Bonding pads may also provided on a wall portion of the recess

The electrical contact towards external may be made through a ball grid array (BGA), one bump thereof being shown as 95, or in flip chip technology.

In the following, some preferred measures and dimensionings are given that may, but need not apply:

The width W of the bottom portion 14 is smaller than 10 mm, preferably smaller than 6 mm, larger than 0.5 mm, preferably larger than 1 mm, wherein the width may be one of the sides of a rectangular bottom portion, or the diameter of a circle of the same area.

The depth D of the recess is smaller than 3 mm, preferably smaller than 1.5 mm or 0.5 mm, larger than 0.1 mm, preferably larger than 0.2 mm.

The ratio of depth D to width W is larger than 0.05, preferably larger than 0.1, and may be smaller than 1, preferably smaller than 0.5. The overall thickness T of the substrate 11 is smaller than 10 mm, preferably smaller than 6 mm, more preferably smaller than 4 mm. The depth G of a groove 16 is smaller than 2 mm, preferably smaller than 1.5 mm.

The angle [alpha] of an oblique wall portion is preferably larger than 20° and may be smaller than 70°. It may be between 40° and 60°, preferably between 54° and 55°, particularly for Si material. But the wall portion may also be more or less vertical, i.e. the angle α being 90°+/−10% or 5%.

The pitch P of adjacent LEDs 20 is larger than 1 mm, preferably larger than 3 mm, and may be smaller than 10 mm, preferably smaller than 8 mm.

The electrical input power of one LED chip may be above 1 W, preferably above 2 or 5 W, and may be below 50 W, preferably below 20 W.

The material of the substrate 11 may be or comprise silicon, either as a single crystal or polycrystalline. It may be undoped. It may be a single crystal or polycrystalline. The material may also be or comprise ceramics, metal or a resin/polymer, the latter preferably filled with a heat conducting material, such as ceramics or silicon particles.

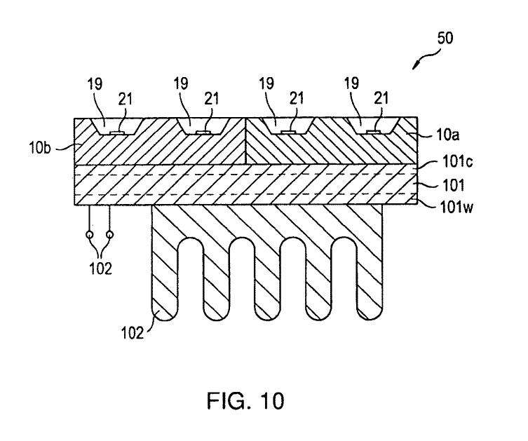

In a further aspect of the disclosed embodiments, as shown in FIG. 10, an LED assembly 50 comprises a mounting structure 10, one or more LED chips 21 on said mounting structure and appropriate wiring for the LED chips. The LED assembly including the wiring and/or the mounting structure may be formed as explained above. The assembly further comprises a thermo-electric cooling element 101 on which the mounting structure is mounted.

The cooling element may be a Peltier element. Insofar, FIG. 10 is only a qualitative image and not a true schematic representation of a possible cross-sectional view.

The cooling element has, or may be driven such that it has, a cold side/surface 101c and a warm side/surface 101w. The mounting structure may be mounted on the cold surface and may be mounted without a sub-mount inbetween, i.e. directly on the cooling element.

The contour of the cooling element or of plural cooling elements side by side may be matching to that of the LED assembly or of plural LED assemblies side by side. FIG. 10 shows two LED assemblies 10a, 10b on one Peltier cooling element 101. 102 are electrical connections of the cooling element. They may, however, be combined with those of the LED assembly.

Fixation amongst cooling element and mounting structure may be made with adhesive, or through mechanical clipping or other appropriate means.

The thermoelectric (Peltier) cooling element may form the cover for grooves 16 as shown in FIG. 1. In such an embodiment, the fluid cooling and the thermoelectric cooling may be used in combination. But likewise, the thermoelectric cooling may be used without fluid cooling. Then the mounting structure may be without grooves or channels therein and may have a substantially flat surface or a surface complimentary to that of the thermoelectrical cooling element.

In another embodiment, one of the surface plates of the cooling element may immediately be the substrate 11 of the mounting structure. In such a construction, mounting structure 10 and cooling element 101 are no longer discernible units.

A cooling body 102 may be provided on the warm side/surface 101w of the thermo-electrical element in a heat conducting manner.

1. A mounting structure for at least one LED, comprising,
a substrate, wherein
at least one mounting portion formed in a front surface of said substrate for mounting at least one LED chip thereon, and
cooling grooves or channels for a cooling fluid are formed in the substrate, preferably in or beneath a rear surface thereof.

2. The structure of claim 1, comprising at least one recess formed in said front surface of said substrate, the recess having side walls and a bottom portion, the bottom portion constituting said mounting portion for the LED chip.

3. The structure according to claim 2, wherein one or more or all of the side walls comprise a step structure.

4. The structure of claim 3 wherein one or more steps of the step structure are adapted to carry one or more bonding pads for wire bonding towards an LED chip.

5. The structure of claim 2 in which the bottom portion comprises a substantially flat plane surrounded by the side walls of the recess that extend from the bottom portion towards the front surface.

6. The structure of claim 5 wherein the ratio U/W of depth D of the recess and width W of the bottom portion is between 0.05 and 1, preferably between 0.1 and 0.5.

7. The mounting structure according to claim 5, wherein one or more or all of the side walls are or comprise a substantially flat or curved plane portion.

8. The structure according to claim 7, wherein one or more or all of the side walls are reflective, preferably by being provided with a reflective coating.

9. The structure according to claim 8, wherein one or more or all of the side walls comprise an oblique portion with respect to the front surface, the angle α being preferably in a range between 20° and 70°.

10. The structure according to claim 9, wherein the contour of the recess in the front surface and/or the contour of the bottom portion is rectangular, preferably square or circular.

11. The structure according to claim 10, wherein the recess is formed by etching and properties of one or more or all of the side walls are determined by etching properties.

12. The structure according to claim 11, comprising plural recesses, preferably regularly arranged, more preferably in a rectangular matrix pattern.

13. The structure of claim 12, where portions of the front surface (12) remain between adjacent recesses.

14. The structure according to claim 1, comprising one or more circuit elements and/or wiring formed on the substrate.

15. The structure of claim 14, wherein the circuit elements are driving circuit elements for an LED.

16. The structure according to claim 1, wherein the substrate comprises silicon and/or ceramics and/or a polymer and/or metal.

17. The structure of claim 1 wherein the substrate is formed of plural layers stacked in a widthwise direction and bonded to each other, wherein preferably a cooling groove is provided at the interface between two adjacent layers.

18. The structure of claim 17, wherein each of the layers comprises silicon and/or ceramics and/or a polymer and/or metal, wherein the material of different layers may be different.

19. The structure according to claim 1, comprising one or more of the following features:
the depth D of the recess is smaller than 3 mm, preferably smaller than 1 mm, and/or larger than 0.1 mm, preferably larger than 0.3 mm,
the width W of the bottom portion is smaller than 10 mm, preferably smaller than 6 mm, and/or larger than 0.5 mm, preferably larger than 2 mm,
a cooling groove under a recess is formed straight or bent or meandering, plural cooling grooves are formed under a recess,
the substrate comprises silicon and/or a ceramics material.

20. An LED assembly comprising:
a mounting structure according to one or more of the preceding claims, in one or plural or all of the recesses at least one LED chip,
first electric connecting means allowing electrical connection to external electric components,
wiring from the connecting means towards the LED chips, and first fluid connecting means allowing fluid connection of the cooling channels to external cooling components.

21. The assembly of claim 20, comprising a colour conversion substance in one or more or all of the recesses above the LED chips.

22. The assembly of claim 20, comprising a scattering substance in one or more or all of the recesses above the LED chips.

23. The assembly of claim 20, comprising plural recesses with respectively an LED chip therein, the plural LED chips having different spectral emission characteristics, particularly different colours.

24. The assembly according to claim 20, wherein plural LED chips are provided in one recess, said plural LED chips having different spectral emission characteristics, particularly different colours.

25. The assembly according to claim 24, comprising an integrated circuit on the substrate.

26. The assembly according to claim 25, comprising a cover on the surface in which cooling grooves are formed for closing said grooves for forming cooling channels.

27. The assembly according to claim 26, wherein the first electric connecting means and the first fluid connecting means are plug-like connecting means having a common plugging direction that is preferably vertical to the plane of the mounting structure.

28. The assembly according to claim 27, wherein the distance M between the centre of the border LED chips and the edge of the assembly is not larger than half the pitch P amongst adjacent recesses.

29. The assembly according to claim 28, comprising one or more of the following features:
the assembly comprises a rectangular n*m matrix arrangement of LEDs, n and m being integers preferably larger than 10, the pitch amongst respective centres of adjacent recesses is smaller than 10 mm or smaller than 8 mm, and/or higher than 1 mm, preferably higher than 2 mm,
the cooling channels are liquid-tight,
the recesses are formed by etching, preferably by wet etching,
the substrate is made of polycrystalline silicon,
the input power of a single LED chip is higher than 1 W, or higher than 5 W and/or lower than 50 W or 20 W.

30. A socket for an LED assembly according to claim 29, comprising:
a receptacle for said LED assembly, the receptacle comprising:
second electric connecting means allowing electrical connection to the first electric connecting means of the LED assembly, and
second fluid connecting means allowing fluid connection to the first fluid connecting means of the LED assembly.

31. The socket of claim 30, comprising holding means for holding the LED assembly.

32. The socket of claim 30, comprising plural receptacles for plural LED assemblies.

33. A method for forming a mounting structure for at least one LED, comprising:
preparing a substrate comprising silicon and/or another semiconductor and/or ceramics and/or a preferably filled polymer and/or a metal, and
forming one or more cooling grooves or channels for a cooling fluid in the substrate, preferably in or beneath a rear surface thereof.

34. The method of claim 33, wherein forming the cooling grooves is made by dry or wet etching.

35. The method of claim 33, comprising the step of preparing at least two layers, forming said grooves in at least one of said layers, and adhering the layers for forming the substrate such that the one layer closes the grooves formed in the other layer for forming a coolant channel.

36. The method according to one or more of the claim 33, comprising the step of forming one or more recesses for mounting an LED chip in a substrate surface.

37. An LED assembly comprising a mounting structure and one or more LED chips on said mounting structure, the LED assembly preferably being formed in accordance with claim 20, comprising:
a thermo-electric cooling element on which the mounting structure is mounted.

38. The assembly of claim 37, wherein a coolable surface plate of the thermo-electric cooling element is directly attached to, or is formed uniform with, the mounting structure.
